(19) United States
(12) Patent Application Publication
(10) Pub. No.: US 2024/0113506 A1
(43) Pub. Date: Apr. 4, 2024

(54) OPTOELECTRONIC DEVICE AND METHOD

(71) Applicant: ams-OSRAM International GmbH, Regensburg (DE)

(72) Inventors: Zeljko PAJKIC, Regensburg (DE); Michael MUELLER, Eching (DE); Simon JEREBIC, Donaustauf (DE)

(21) Appl. No.: 18/264,768

(22) PCT Filed: Feb. 9, 2022
(86) PCT No.: PCT/EP22/53179

§ 371 Date: Aug. 9, 2023

(30) Foreign Application Priority Data
Feb. 10, 2021 (DE) 10 2021 103 147.8

(51) Int. Cl. H01S 5/068; H01S 5/02257; H01S 5/0239

(52) U.S. Cl. CPC H01S 5/06825; H01S 5/02257; H01S 5/0239

(57) ABSTRACT

An optoelectronic device includes a substrate carrier and a light source arranged thereon, which has a main radiation direction. A cap with an optical element is arranged above the light source and connected to the substrate carrier. This is arranged in the main radiation direction of the light source. Furthermore, a sensor device is provided, which is designed to emit a wireless signal between the cap and the substrate carrier for detecting damage to the cap. For this purpose, the cap is designed to interact with the emitted wireless signal.

The present application is a U.S. National Stage Application, filed under 35 U.S.C. § 371, of International Application No. PCT/EP2022/053179, filed on Feb. 9, 2022, and claims priority under 35 U.S.C. § 119(a) and 35 U.S.C. § 365(b) from German patent application DE 10 2021 103 147.8 of Feb. 10, 2021, the contents of which is hereby incorporated by reference in its entirety.

### FIELD

Various embodiments of the present disclosure relate to an optoelectronic device and a method for detecting damage to an optical element.

### BACKGROUND

In some optoelectronic applications, such as LIDAR, or even in light projections, lasers are used, among other things, to achieve the necessary luminosity of the light source. These are characterized by extremely high intensity and focus. The high luminosity for laser applications requires that eyes are especially protected from such laser radiation to avoid injuries.

For this purpose, special optical elements are used in components with laser light sources, which surround the laser light source and thus protect the eyes of a user from possible harmful laser radiation. Among other things, the optical elements are constructed with a so-called interlock connection or an interlock feature. For this purpose, an electrical circuit is created between the optical element and an MID cap, which is intended to ensure the correct positioning and an integrity of the optical element for protection against laser radiation. If the electrical circuit is broken, the cap and optical element are assumed to be damaged and the laser light source automatically shuts down.

In conventional devices, the interlock feature is produced by bonding processes in which the adhesive includes electrically conductive elements in the form of silver particles, for example. However, such bonding processes are costly and also have a relatively poor yield, resulting in high costs on the one hand and lower reliability of the device on the other. In addition, a component produced in this way is thermomechanically very sensitive.

Therefore, there is a need to provide optoelectronic devices having such a feature which ensures improved yield while providing sufficient protection against an emitting laser radiation.

### SUMMARY

Embodiments of the present disclosure includes different approaches to detecting possible damage to an optoelectronic device, which involves verifying the correct position and integrity of the cap and the optical element, or a connection between the optical element and the cap, via a wireless signal.

Various embodiments of the present disclosure take advantage of the fact that a change in the position of the optical element, a break in the connection between the optical element and the cap, or even a detachment of the cap leads to a change in the electromagnetic or electrostatic properties within the component. By means of a suitable evaluation of certain electromagnetic parameters, it is thus possible to draw conclusions about possible damage to the component. In this context, the term “electromagnetic or electrostatic property” does not refer to electrical resistance. Rather, “electrostatic properties” means properties such as capacitance, inductance, or generally the imaginary parts of an impedance.

In one aspect, an optoelectronic device is provided comprising a substrate carrier having a light source disposed thereon, in particular a laser light source. The latter has a main radiation direction. The optoelectronic device further comprises a cap arranged above the light source and connected to the substrate carrier, having an optical element arranged in the main radiation direction of the light source. Finally, a sensing device is provided which is adapted to provide a signal between the cap and the substrate carrier for detecting damage to the cap. According to the proposed principle, the cap is adapted to wirelessly interact with the emitted signal.

By the cap interacting wirelessly with the emitted signal, the state of the cap can be inferred by evaluating the signal. Damage to the cap or the optical element changes the signal emitted by the sensor device so that it deviates from a setpoint value, which is detectable by the sensor device.

Embodiments of the present disclosure eliminate the need for more complex adhesives and simplifies the mechanical fabrication of the cap. In particular, it also solves the problem of poor mechanical connections, which occur especially with electrically conductive adhesives, since these are no longer necessary. The proposed detection of possible damage by a sensor device becomes less dependent on external influences such as temperature fluctuations, and the mechanical strength of the component can be improved by now simpler adhesives.

In one aspect, the sensor device is configured to detect a signal interacting with the cap and compare it to a set point. In a further aspect thereof, the sensor device is configured to generate a status signal depending on a deviation of the detected signal interacting with the cap from a setpoint. In this way, different faults can be identified, particularly when the cap interacts with the signal in a fault-dependent manner. For example, if the optical element is damaged, an interaction may be different than if the cap is damaged or partially detached from the substrate. Whereas with conventional devices, damage to the electrical path must occur to indicate a fault, the cap also alters the signal emitted by the sensing device when other damage is present. This can increase the sensitivity of such detection and improve safety.

Some aspects deal with the design of a wireless signal and in particular the emitted wireless signal. For example, this may be a pure carrier signal, but may also have modulation. For example, the emitted signal may have a frequency modulation, an amplitude modulation, or even a phase modulation, or a combination thereof. The modulation is chosen, for example, to produce a particularly strong influence on the modulated signal by changing the mechanical or electrical structure of the cap and/or the element.

Another aspect relates to possible forms or processes that cause an interaction to produce a change in the output wireless signal. In one aspect, the wireless interaction is based on a generation of a wireless signal in response to the emitted signal. Alternatively, the emitted signal may be altered due to a capacitive change in the cap or optical element, particularly due to damage. A further change in the emitted signal may be produced by an inductive change in the cap or optical element or the connection therebetween.

In one aspect, the interaction due to altered electronic properties of the cap and/or the optical element alters a resonant frequency, a frequency, an amplitude, a phase, an attenuation of the emitted signal, or combinations thereof.

In some aspects, the cap for generating the wireless interaction does not itself comprise a dedicated permanent energy storage device, such as a battery. Rather, in some aspects, it is provided that the signal indicated by the sensing device also provides, at least in part, the energy necessary for the interaction.

In one aspect, the cap includes a transmitting element for generating a wireless signal in response to the signal provided. In this way, a particular signal can be generated, thereby directly inferring damage. In one simple form, the transmitting element comprises a resonator that begins to oscillate due to the transmitted energy, thereby generating a response signal. An antenna for this transmitting element comprises at least one conductor loop, in particular outside the main radiation direction, which is arranged in particular on the side of the optical element facing the light source or between the cap and the optical element. An optically transparent electrically conductive material can also be used as the antenna (e.g. ITO). As a result, the antenna can also be located in the main radiation direction.

Alternatively, an antenna can also have an open conductor structure, for example in the form of a dipole or a multipole. Damage to the cap either directly damages the antenna structure, but in any case alters the radiation characteristics of the antenna structure. This can be detected so that reliable detection of damage is ensured. As used herein, the term conductor loop is intended to be understood broadly to include an area spanned by a conductor. In some aspects, as noted, the transmitting element may be co-powered by the signal emitted by the sensing device. In this regard, it may be provided that the transmitting element includes an energy storage device that is itself configured to temporarily store energy from the signal from the sensing device.

In another aspect, purely passive detection is performed. For example, it may be provided that the optoelectronic device comprises at least one conductor loop, in particular outside the main radiation direction. Again, via an electrically conductive material may be provided that is alternatively also in the main radiation direction. This can be arranged in particular on the side of the optical element facing the light source. In an alternative embodiment, at least one conductor loop is arranged between the cap and the optical element. This can be arranged outside the main beam direction, but in the case of transparent materials also inside the beam direction. The conductive loop interacts with the signal emitted by the sensor device in a characteristic manner. When damaged, this characteristic changes to allow detection of the damage.

In one aspect, the sensing device comprises an antenna that is capacitively or inductively coupled to the cap and/or the optical element. The coupling is such that a change in the position of the cap and/or optical element relative to the antenna, or damage to the cap and/or optical element, or even removal of the cap and/or optical element, causes a change in the radiated signal that is detectable by the sensing device.

In another embodiment, at least one conductor loop is disposed between the cap and the substrate support and is located opposite at least one antenna structure that is connected to the sensor device to emit a signal. In the event of damage to a connection between the cap and the substrate carrier, the coupling and thus the interaction of the two elements changes, so that the signal emitted by the sensor device in the conductor loop connected to the sensor device also changes and the damage can thus be detected by the sensor device.

In this regard, the antenna structure may be disposed in or on the substrate support and may be electrically isolated from the conductor loop by a non-conductive adhesive.

In another aspect, the focus is not on an inductive behavior (as in the previous embodiment examples), but on a capacitive interaction. In one aspect, an optoelectronic device according to the proposed principle is further embodied in which the cap and/or the optical element comprises a metallic element for generating a capacitive interaction. This may, for example, have a planar shape.

In a further embodiment, the sensor device comprises a conductor loop arranged around or on the light source. An arrangement on the light source, i.e. close to the optical element may be convenient in some aspects, since a close proximity of the interacting elements makes the interaction particularly large and thus changes in the interaction are easily detectable.

Another aspect relates to a method for detecting damage to an optoelectronic device. In this method, an optoelectronic device or package having
a substrate carrier and a light source, in particular a laser source, arranged thereon, wherein the light source has a main radiation direction. Above the light source, a cap connected to the substrate carrier is arranged with an optical element which faces the main radiation direction of the light source.

For the method, a wireless signal is now generated in the space between the cap and the substrate carrier so that this signal interacts with the cap and/or the optical element. Then, the signal changed by the interaction is detected and compared to a target value. If the detected signal modified by the interaction deviates from a range defined by the set point, a negative state signal is generated. In response to such a generated negative state signal, the light source can be.

Thus, a check for damage is performed using a wireless signal rather than a wired signal, such as a resistance measurement or the like. In one aspect, the generated wireless signal is received to generate energy therefrom. This energy is in turn used to generate and wirelessly output a response signal. Thus, the interaction is performed by a generation of a response signal. The response signal may have a different frequency from the generated signal. This facilitates detection and reduces potential interference between the signals. In another aspect, the generated signal exhibits frequency modulation, amplitude modulation, phase modulation, or a combination thereof.

The interaction of the generated signal with the cap and/or optical element may be based on a generation of a wireless signal in response to the generated signal. Alternatively, a change in the generated signal may be due to a capacitive change. Similarly, the interaction may be due to an inductive change such that a change in the generated signal is thereby caused. In one aspect, the generated signal is changed due to a change in a capacitive or inductive coupling of the cap and/or the optical element with a sensing device caused by damage or a change in position of the cap and/or the optical element.

### BRIEF DESCRIPTION OF THE DRAWINGS

Further aspects and embodiments according to the present disclosure will become apparent with reference to the various embodiments and examples described in detail in conjunction with the accompanying drawings.

FIG. 1 shows a representation of an optoelectronic device having a conventional interlock feature;

FIG. 2 shows a representation of an optoelectronic device with an interlock feature according to at least one embodiment of the present disclosure;

FIG. 3 shows a representation of an optical element according to at least one embodiment of the present disclosure;

FIG. 4 illustrates a second embodiment with further aspects of the present disclosure;

FIG. 5A is a top view of an optical element according to at least one embodiment of the present disclosure;

FIG. 5B is a top view of another optical element according to at least one embodiment of the present disclosure;

FIG. 6 shows a third embodiment for exemplifying further aspects of the present disclosure;

FIG. 7 is a top view of a substrate carrier with some aspects of the present disclosure;

FIG. 8 shows a fourth embodiment for exemplifying further aspects of the present disclosure;

FIG. 9 is an illustration of a method according to at least one embodiment of the present disclosure.

### DETAILED DESCRIPTION

The following embodiments and examples illustrate various aspects and combinations of the present disclosure. The embodiments and examples are not always to scale. Likewise, various elements may be shown enlarged or reduced in size to highlight individual aspects. It will be understood that the individual aspects and features of the embodiments and examples shown in the figures may be readily combined with each other without affecting the principle of the present disclosure. Some aspects have a regular structure or shape. It should be noted that minor deviations from the ideal shape may occur in practice, but without contradicting the inventive idea.

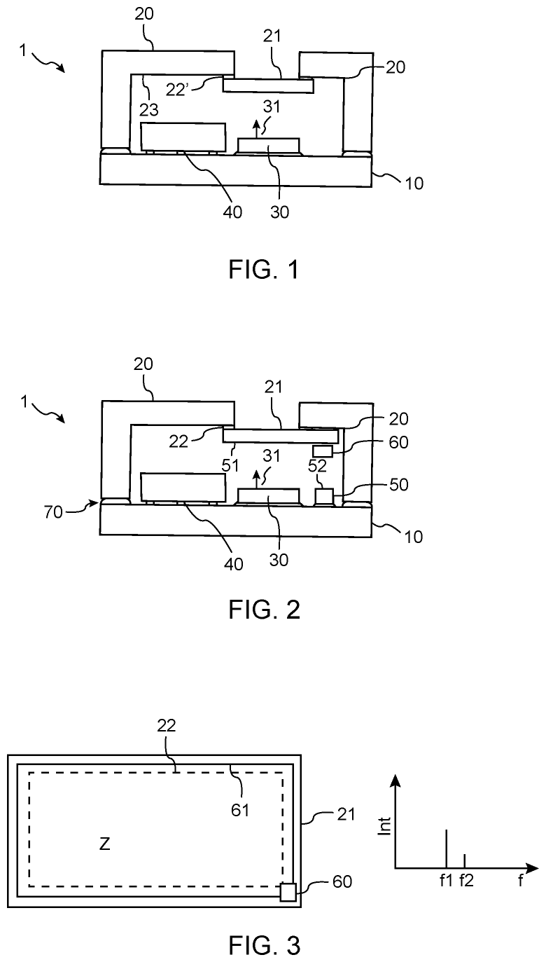

FIG. 1 shows a representation of an optoelectronic device with a conventional interlock feature as a so-called package. The optoelectronic device 1 comprises a substrate carrier 10 with a light source 30 arranged thereon. The light source 30 is designed here as a vertically emitting laser, VCSEL for short, the laser light of which is emitted in an upward mode along the main emission direction 31. A control circuit 40 is further mounted on the substrate carrier 10 and electrically contacted with the light source 30. The substrate carrier 10 further includes vias contacting the chip 40 and the light source 30, which are not shown here for clarity.

A MID cap 20 is attached to the substrate carrier 10. This is made of a non-conductive material and comprises an opening in which an optical element 21 is inserted. The opening is arranged here above the light source in the main radiation direction 31. The optical element 21 is thus located above the main radiation direction of the light source 30.

For a detection of a damage of the cap 20 or the optical element 21, respectively, an electrical conductor 23 is provided in this conventional component, which runs along a side wall of the cap and is subsequently electrically conductively connected to the optical element 21. The electrically conductive connection is made via a conductive adhesive 22, with which the optical element 21 is connected to the cap 20, around the opening.

In one operation of this arrangement, the control chip 40 generates a current through the conductor 23 and along the conductive adhesive connection 22. If the conductive adhesive connection 22 is damaged, this conduction is electrically interrupted so that current can no longer flow through the conductor 23 and the voltage drop is increased. This can be detected by the sensing device 40 so that the control circuit 40 turns off the light source in response. In this simple embodiment, in addition to an electrical connection of the cap to the optical element, a connection of the substrate to the cap can also be verified by means of the same method.

In the manufacture of such a package, two different adhesives are often used to produce the necessary mechanical and electrical properties. An electrically conductive adhesive has a much lower bonding ability compared to a normal non-conductive adhesive, so in addition to the electrically conductive adhesive, an electrically non-conductive adhesive is also necessary for structural reinforcement. However, these two exhibit different mechanical properties and, in particular, different coefficients of thermal expansion. In operation of such an arrangement, a connection can break off due to the different thermal expansion coefficients and thus a false or faulty signal can be generated.

FIG. 2 now illustrates an embodiment of an electronic device with an interlock feature according to the proposed principle. As in the previous example with a conventional component, the optoelectronic device or package according to the proposed principle comprises a substrate carrier 10 on which a light source 30 in the form of a laser light source is applied. A control circuit 40 is provided for controlling the laser light source. In addition, a sensor device 50 is arranged on the substrate carrier. As in the above example, the substrate carrier includes a plurality of vias leading to contact pads (not shown here) on the side facing away from the opening of the cap 20.

In this and the following embodiments, the control circuit 40 and the sensor device 50 are shown as separate elements. However, in practical implementation, it is conceivable to integrate the sensor device into the control circuit 40. Similarly, the embodiments show that the control circuit 40 and the sensor device 50 are arranged within the space enclosed by the cap 20 and the substrate 10. This may be convenient in some embodiments, as such an electronic device can be manufactured and used as an integrated package. Alternatively, however, provision may be made to provide the control circuitry 40 and sensor device 50 outside the cap on the substrate support 10. In such a case, the cap may be designed with smaller dimensions. Referring again to FIG. 2, the optoelectronic device 1 comprises a cap 20 attached to the substrate support 10 by means of an adhesive 70. In this embodiment, the adhesive 70 is a non-conductive adhesive and is used to mechanically secure the cap 20 to the substrate support 10 in a stable manner. Cap 20 comprises, as in the previous example, an optical element 21 located above the main emission direction of the light source 30. In this embodiment, the opening of cap 20 is unobstructed and covered only by optical element 21. In other embodiments not shown here, the opening may also be filled with a transparent material or the optical element 21 may be arranged within the opening.

The optical element 21 is attached to the perimeter of the cap 20 with an adhesive 22. Here, the adhesive 22 is also a non-conductive adhesive, so that a good mechanical attachment of the optical element 21 to the cap material is achieved.

The optical element 21 has an antenna structure 61 on its side facing the light source, which is connected to a transmitter element 60. The transmitter 60 is also arranged on the optical element, but is located outside the main radiation direction of the light source 30. In this embodiment example, the transmitter is arranged directly opposite the sensor device 50.

FIG. 3 shows a top view of the optical element 21, which is transparent and has a transparent window in its center Z through which the laser light can be emitted. In its edge region, the optical element 21 contains a transmitter 60 which is electrically conductively connected to an antenna structure 61. The antenna structure is shown here in simplified form as a single conductor loop, but in practical embodiments this may comprise multiple loops and may be designed, for example, as a loop antenna. Also, the antenna structure 61 may comprise multiple separate conductor loops such that they may serve as both a transmitting and a receiving antenna. In the top view, the area of the adhesive connection 22 is shown by a dashed line. The adhesive connection 22 is formed on the other side of the optical element, so that the optical element is attached to the cap on its side away from the light source.

In one operation, the sensor device 50 generates a transmitted electromagnetic signal at a frequency f1 which is radiated into the space of the optoelectronic device surrounded by the cap 20 and the optical element 21 via an antenna 52. The transmitted signal emitted by the sensing device is received by the antenna structure 61 and converted in the transmitter 60 to generate, among other things, the energy necessary to generate the response. In other words, the electromagnetic signal emitted by the sensing device 50 generates a voltage pulse in the antenna structure 61 that is rectified and temporarily stored in a capacitor or energy storage device within the transmitter 60. In the further course, the energy stored in the capacitor of the transmitter is sufficient to generate a response signal with the frequency f2 in response to the signal emitted by the sensor 50 and to radiate it via the antenna structure 61. This frequency may be the same as the frequency f1, but may also be different. The latter is expedient, since this means that the two signals do not interfere with each other, or only slightly. In addition, the frequencies can be selected in such a way that they can be easily mixed down and further processed in the sensor device, for example.

The antenna structure 61 is thus used both as a receiver for the signal emitted by the sensor device and as an antenna for the transmitted signal. Alternatively, different antenna structures can be used for this purpose, which may be useful in the case of different transmitting and receiving frequencies, since these can now be specifically set to the respective transmitting and receiving frequency. In summary, the transmitter 60 thus interacts with the signal emitted by the sensor 50 and in response generates a signal which is in turn radiated into the space enclosed by the cap. The sensor 50 can detect and evaluate this with its receiving and transmitting antenna 52.

In a normal operation, the sensor device 50 detects the emitted signal, evaluates it and compares it, for example, with a setpoint. If the received signal matches the setpoint within a certain range, it can be assumed that the optical element 21 and the cap 20 are intact. If, on the other hand, the optical element 21 is mechanically damaged, two cases can be distinguished.

In the first case, the mechanical damage also damages the conductive loop 61, so that it is impossible or at least severely impaired to radiate or even receive the signal emitted by the sensor device 50. As a result, the sensor device no longer receives a response signal in response to the signal it emits, for example, and thus generates a status signal to the control device 40 that leads to the light source 30 being switched off. In a second case, the damage to the optical element 21 or cap is not sufficient to produce an interruption of the conductive loop 61. Nevertheless, the damage results in a change in the characteristic radiation property of the antenna structure 61 such that, for example, the frequency or amplitude of the response signal from the transmitter 60 changes. The changed response signal can be detected and evaluated by the sensor device 50. If the deviation from a target value is sufficiently large due to the damage of the optical element 21 or the cap 20, this is indicated by the sensor device to the control circuit 40 and the light source 30 is switched off for safety.

In this way, the sensor device 50 is able to detect damage to the cap 20 and the optical element 21 without having to break an electrical connection in the form of the antenna structure 61. This ensures the safety of the device, since damage is also detected that does not lead to an interruption of the conductor loop but to a significant change in the radiation characteristics of the antenna structure 61.

An example of such a change here would be a hole within the optical element 21 in the region of the center Z, which is located outside the conductor loop 61 but within the main radiation direction 31. This hole may result in increased radiation and thus an increased risk of injury to a user. The hole greatly alters the environment of the antenna structure 61, so that its radiation characteristics are also altered. According to the proposed principle, this change is detected by the sensor device and identified as damage.

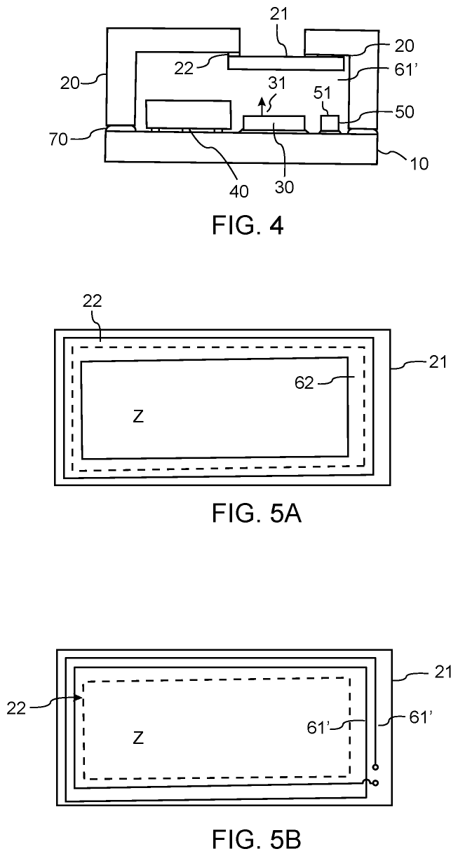

FIG. 4 shows a second embodiment of an optoelectronic device according to the proposed principle. Components with the same function have the same reference signs. In this embodiment, the optical element 21 is designed only with a special antenna structure 61′, but has no further transmitter. In the example, the antenna structure 61′ is implemented in the form of several conductor loops on the underside, i.e. on the side facing the light source as well as on the opposite side. This creates an inductive coupling between the top and bottom sides of the optical element.

However, it is thus designed as a purely passive structure. The sensor device 50 further comprises an integrated transmitting and receiving unit with an antenna 51, which is also integrated in the sensor device 50 as in the previous example. Due to the spatial proximity, the transmitting antenna 51 thereby interacts electromagnetically with the structure 61′ of the optical element 21. In other words, the properties of the antenna 51 are influenced by the structure 61′ of the optical element 21. The inventors now make use of this influence in a suitable manner.

In one operation, the sensor device 50 generates a transmit signal and radiates it via the antenna 51. In a normal operation, the interaction between the structure 61′ and the antenna 51 alters the radiation of the signal from the sensor device 50 or even the transmitted signal itself in a characteristic manner. For example, the antenna 51 as well as the structure 61′ on the optical element 21 are matched to each other in such a way that a particularly low or particularly high reflection results for the transmitted signal to be emitted. Thus, with such a mismatch, either only a small portion of the transmitted signal or a very large portion is reflected back into the sensing device. This can be detected and a change in this part can be evaluated. In other words, the sensor device is designed, for example, to detect a reflection or other characteristic of the antenna system (comprising structure 61′ and antenna 51).

If the optical element 21 or the cap 20 is damaged, this system of antenna 51 and structure 61′ on the optical element is now changed, so that their reflection and radiation characteristics also change. This too can now be detected by the sensor device, compared with a setpoint value and further evaluated. In one example, it is envisaged that the system comprising the antenna 51 and the structure 61′ on the optical element is in a particularly good resonance. Damage to the cap 20 or the optical element now leads to a mismatch of this overall system, resulting in increased reflection, or the radiated power is changed. This change is detected by the sensor device and identified as damage.

Various embodiments are conceivable for the passive structure 61 of the optical element 21, which interacts with the signal emitted by the sensor device 50.

FIGS. 5A and 5B show two such embodiments based on capacitive and inductive coupling and interaction, respectively. FIG. 5A shows an embodiment for generating a capacitive interaction. Here, a relatively wide metallic strip 62 is arranged around the center Z on the optical element 21. This metallic strip may be present on both sides of the optical element. The metallic structure 62 can be two-dimensional and may cover part of the area of the adhesive joint 22, as shown here. Alternatively, it may extend to the edge of the optical element 21.

In one operation of this arrangement, an interaction of the emitted signal with the metallic strip 62 takes place via capacitive coupling. In the event of damage, for example a tear-off of the optical element, the distance of the metallic strip 62 from the emitting structure 51 of the sensor device 50 may change, among other things, which in turn changes the capacitive coupling and thus the imaginary component of the impedance of the overall system. This can be detected and evaluated by the sensor device 50.

FIG. 5B shows an alternative embodiment in which an inductive interaction takes place instead of a capacitive coupling and interaction. For this purpose, a plurality of conductor loops 61′ are arranged in the region above the adhesive joint 22 on the optical element around the transparent center Z. The structure in the form of multiple conductor loops generates an electromagnetic response when a signal changes, causing interaction with the emitted signal. Again, damage alters the characteristic properties of these conductor loops so that they can be detected and evaluated by the sensor device.

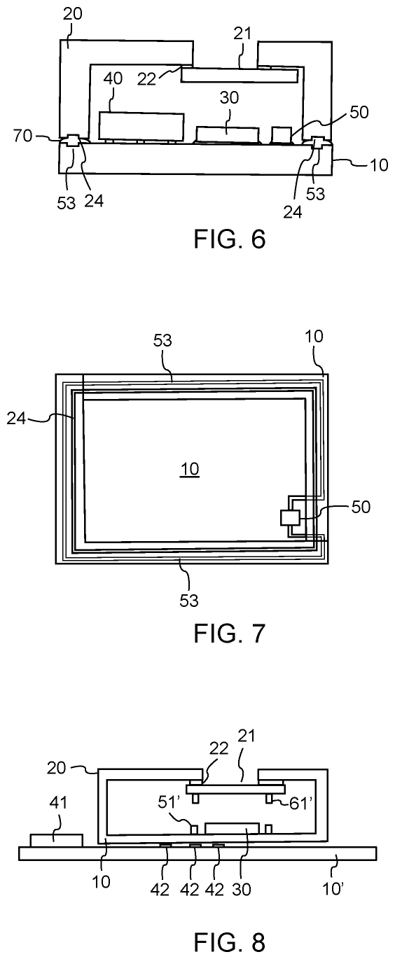

FIG. 6 shows a further embodiment of a package according to the proposed principle, in which damage between, among other things, the cap 20 and the substrate carrier 10 is to be detected and identified. Thereby, this embodiment according to FIG. 6 can also be combined with the already mentioned embodiments.

In this embodiment, the cap 20 is attached to the substrate carrier 10 by means of a non-conductive adhesive 70. Also arranged on the substrate carrier 10, as in the preceding embodiments, are the light source 30 in the form of a laser light source, the control circuit 40, and the sensor device 50. An antenna 53 is now attached to the side of the substrate carrier in the area of the adhesive, i.e. in the area below the position of the cap 20, which is capacitively or also inductively coupled to a further structure 24 on the cap side and thus interacts with the latter. The two structures 24 and 53 are electrically separated from each other by the non-conductive adhesive 70.

FIG. 7 shows a top view of substrate carrier 10 illustrating said structure. Substrate carrier 10 includes sensor device 50 to which antenna 53 is connected in the form of a conductor loop structure. As in the other embodiments, this may be one or more individual loops. However, the structure 53 may also have another shape, for example in the form of a dipole or the like. Above the antenna 53 in the area of the cap 20, another metallic closed conduit 24 is provided, which is integrated in the cap 20. The two elements 24 and 53 are thus electrically isolated from each other even by the non-conductive adhesive 70. Nevertheless, capacitive or inductive coupling occurs between the antenna 53 and the metallic structure 24 due to their close proximity.

In one operation, the sensing device generates a signal in the antenna structure 53, which in turn capacitively and/or inductively couples with the metallic structure 24, causing a characteristic response. If the cap 20 is damaged, for example by breaking the adhesive connection 70, the coupling between the structure 24 and the antenna 53 is altered and thus the radiation characteristic is disturbed. This disturbance can be detected by the sensor device 50 and identified as possible damage.

FIG. 8 shows another embodiment a package according to the proposed principle. In this embodiment, the control circuitry as well as the sensor device is arranged outside the actual package, whereby the latter can be designed to be particularly space-saving and spatially small.

The embodiment comprises a PCB carrier 10′ on which an integrated control and sensor circuit 41 is arranged. This is connected via leads to a plurality of contact pads 42, which in turn are in electrically conductive connection with through-platings in the substrate carrier 10. The vias lead to the light source 30 in the form of a VCSEL. The light source 30 is arranged directly over an opening in the cap 20 and the optical element 21 covering the opening.

An antenna structure 51′ is arranged around the light source 30, which is connected to the integrated sensor and control circuit 41 via the vias. The antenna structure 51′ may also be arranged on the surface of the CVSEL. A corresponding passive structure 61′ according to one of the aforementioned embodiments is attached to the optical element 21 and is located in the direct spatial vicinity of antenna 51′. Thus, a particularly high capacitive or inductive coupling between the antenna 51 and the passive structure 61 on the optical element 21 is achieved.

If the cap 20 or the optical element 21 is damaged, this coupling between the antenna 51 and the passive structure 61′ is disturbed, and the disturbance is detected by the integrated control and sensor circuit 41 on the basis of a change in the emitted signal.

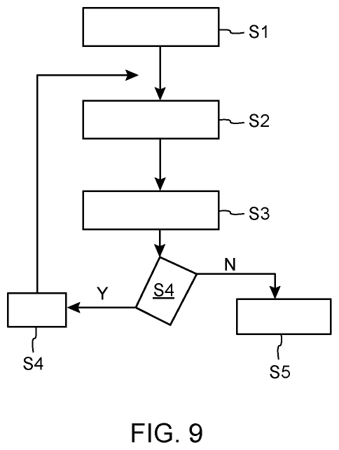

FIG. 9 shows an embodiment of a method for detecting damage in an optoelectronic device according to the proposed principle. In a first step S1, an optoelectronic device is provided which has a cap attached to a substrate carrier with an optical element integrated therein. The optical element is designed to be at least partially transparent in a center, so that light from a light source can radiate through the optical element. For this purpose, the light source is enclosed by the cap and the optical element.

In a step S2, an electromagnetic signal is now generated and emitted, in particular, into the space between the cap and the substrate carrier. The electromagnetic signal interacts with the elements of the optoelectronic device and in particular with the optical element as well as the cap. In this case, structures can be applied to or integrated in the optical element or the cap, which effect an electromagnetic coupling with a transmitting structure for the emitted signal and thus interact with the emitted signal. In addition to purely passive structures, these can also be active structures. for example, the emitted signal can be detected and used to generate a second response signal. For the purposes of this description, the interaction or the signal modified by the interaction thus corresponds to the generated response signal.

In step S3, the signal modified by the interaction is detected and further processed, i.e., compared with a setpoint value, for example. If the change is within a certain range of the nominal value, it is assumed in step S4 that the component is intact and has no damage. In such a case, step S4 is continued by generating a status signal indicating an intact component. A control circuit then activates the light source so that light is emitted through the optical element. The process then returns to step S2 and repeats steps S2 to S5 at periodic intervals. On the other hand, if it is detected in step S4 that the detected signal is outside a certain range around a desired set point, a status signal indicating damage is generated. In step S5, this status signal leads to a shutdown or deactivation of the light source in order to avoid damage.

The embodiments and examples shown here can be combined in various ways. In particular, the inventors have in mind to detect a possible damage not via a resistive change, for example due to a conductor break, but with the help of a wireless signal and the coupling of the different elements to each other. This coupling leads to an interaction with the signal emitted by the sensor device, so that this can be evaluated and a decision about possible damage can be made based on the evaluation. The various embodiments are not limited to the embodiments shown.

For example, the embodiments in FIGS. 5A and 5B refer to the optical element. However, this embodiment may also show the carrier substrate such that the conductor loops or even the metallic strip are disposed between the carrier substrate 10 and the cap 20. Likewise, it is possible to provide several such elements at different positions (e.g., between cap and optical element, on the optical element, or between cap and carrier substrate) that couple capacitively or even inductively, leading to an interaction. This allows damage to be detected at different points.

### REFERENCE LIST

1 optoelectronic device
10 substrate carrier
10′ PCB carrier
20 cap
21 optical element
22 adhesive
22′ adhesive
23 conductor
30 light source, VCSEL
31 main radiation direction
40 control circuit, IC
41 control circuit with integrated sensor device
50 sensor device
51, 51′ antenna
52 antenna
53 antenna
60 transmitter
61 antenna structure
70 adhesive
Z transparent area

What is claimed is:

1. An optoelectronic device, comprising:
a substrate carrier with a light source arranged thereon having a main radiation direction;
a cap arranged above the light source and connected to the substrate carrier, having an optical element arranged in the main radiation direction of the light source;
a sensor device adapted to emit an electromagnetic signal between the cap and the substrate carrier for detecting damage to the cap; wherein
the cap is adapted for wireless interaction with the emitted electromagnetic signal;
wherein
the cap comprises a transmitting element for generating a wireless signal in response to the emitted electromagnetic signal; and
wherein
the transmitting element comprises a temporary energy storage for storing energy from the electromagnetic signal emitted by the sensor device.

2. The optoelectronic device according to claim 1, wherein the sensor device is adapted to detect a signal interacted with the cap and to compare it with a set point.

3. The optoelectronic device according to claim 2, wherein the sensor device is configured to generate a status signal in dependence on a deviation of the detected signal interacted with the cap from a setpoint value.

4. The optoelectronic device according to claim 1, wherein the output electromagnetic signal is a wireless signal, and/or a frequency, amplitude or phase modulated signal.

5. The optoelectronic device according to claim 1, wherein the wireless interaction is based on at least one of the following:
a generation of a wireless electromagnetic signal in response to the emitted electromagnetic signal;
a change in the emitted electromagnetic signal due to a capacitive change;
a change in the delivered electromagnetic signal due to an inductive change.

6. The optoelectronic device according to claim 1, wherein the cap comprises an antenna structure for the transmitting element comprising at least one of the following elements:
at least one conductor loop which is arranged in particular on the side of the optical element facing the light source or between the cap and the optical element;
an open conductor structure forming a di- or multipole.

7. (canceled)

8. The optoelectronic device according to claim 1, wherein the wireless interaction through the cap causes a change in a radiation characteristic of the electromagnetic signal emitted by the sensor device.

9. The optoelectronic device according to claim 1, wherein the sensor device comprises an antenna, which is capacitively or inductively coupled to the cap and/or the optical element in such a way that a change in the position of the cap and/or the optical element relative to the antenna or damage to the cap and/or the optical element or removal of the cap and/or the optical element causes a change in the emitted electromagnetic signal which can be detected by the sensor device.

10. The optoelectronic device according to claim 1, wherein the optical element comprises at least one conductor loop which is arranged on the side of the optical element facing the light source.

11. The optoelectronic device according to claim 1, wherein the optical element comprises at least one conductor loop, arranged between cap and optical element.

12. The optoelectronic device according to claim 1, wherein the optical element comprises at least one conductor loop is arranged between cap and substrate carrier, wherein the at least one conductor loop is located opposite at least one antenna structure, which is connected to the sensor device for emitting a signal.

13. The optoelectronic device according to claim 12, wherein the antenna structure is applied in or on the substrate carrier.

14. The optoelectronic device according to claim 12, further comprising a non-conductive adhesive that electrically separates the antenna structure and the conductor loop.

15. The optoelectronic device according to claim 1, wherein the cap and/or the optical element comprises an electrically conductive material for generating a wireless and/or capacitive and/or inductive interaction with the emitted signal.

16. The optoelectronic device according to claim 1, wherein the sensor device comprises an antenna structure arranged around or on the light source.

17. The optoelectronic device according to claim 1, further comprising a control circuit connected to the light source for driving the light source and adapted to drive the light source in dependence on a state signal from the sensor device.

18. A method for detecting damage to or removal of an optoelectronic device comprising:
providing an optoelectronic device having
a substrate carrier and a light source arranged thereon, in particular a laser source, which comprises a main radiation direction
a cap arranged above the light source and connected to the substrate carrier, comprising an optical element arranged in the main radiation direction of the light source;
generating a wireless electromagnetic signal in the space between the cap and the substrate carrier, said wireless electromagnetic signal interacting with the cap and/or the optical element;
detecting a response signal modified by the interaction and comparing it to a set point;
generating a negative state signal if the response signal modified by the interaction deviates from a range defined by the set point;
deactivating the light source in response to a generated negative state signal;
wherein generating a wireless electromagnetic signal comprises:
receiving the generated wireless electromagnetic signal;
partially converting the received wireless electromagnetic signal to electrical energy to generate the response signal; and
generating the response signal.

19. (canceled)

20. The method according to claim 18, wherein the generated signal is a frequency, amplitude, or phase modulated signal.

21. The method according to claim 18, wherein the interaction of the generated electromagnetic signal with the cap and/or the optical element is based on at least one of the following:
a generation of a wireless signal in response to the generated electromagnetic signal;
a change in the generated electromagnetic signal due to a change in capacitive coupling;
a change in the generated electromagnetic signal due to a change in an inductive coupling.

22. The method according to claim 18, wherein the generated electromagnetic signal is changed due to a damage or a removal or a change of position of the cap and/or the optical element caused change of a capacitive or inductive coupling of the cap and/or the optical element with a sensor device.
